(19) United States
(12) Patent Application Publication
(10) Pub. No.: US 2026/0123053 A1
(43) Pub. Date: Apr. 30, 2026

(54) ARRAY SUBSTRATE, PREPARING METHOD THEREOF, AND DISPLAY PANEL

(71) Applicant: Guangzhou China Star Optoelectronics Semiconductor Display Technology Co., Ltd., Guangzhou (CN)

(72) Inventors: Huanqin ZHENG, Guangzhou (CN); Hui XIAO, Guangzhou (CN)

(73) Assignee: Guangzhou China Star Optoelectronics Semiconductor Display Technology Co., Ltd., Guangzhou (CN)

(21) Appl. No.: 19/028,585

(22) Filed: Jan. 17, 2025

(30) Foreign Application Priority Data
Oct. 29, 2024 (CN) 202411524272.1

(51) Int. Cl. H10D 86/60; H10D 30/67; H10D 86/40

(52) U.S. Cl. CPC H10D 86/60; H10D 30/6737; H10D 86/451

(57) ABSTRACT

The present application provides an array substrate, a preparing method thereof, a display panel. The array substrate includes a substrate and a first conductive layer, an active layer, a second conductive layer and a third conductive layer all provided on the substrate. A source contact portion of the active layer is connected to a source electrode of the first conductive layer. The second conductive layer includes a gate electrode disposed correspondingly to a channel portion. A pixel electrode of the third conductive layer is connected to a drain contact portion of the active layer. At least one of the first conductive layer and the second conductive layer further includes a common electrode disposed corresponding to the pixel electrode.

### CROSS-REFERENCE TO RELATED APPLICATIONS

This application claims priority to Chinese Patent Application No. 202411524272.1, filed on Oct. 29, 2024, the application of which is incorporated herein by reference in its entirety.

### TECHNICAL FIELD

The present application relates to the field of display technology, and particularly to an array substrate, a preparing method thereof, and a display panel.

### BACKGROUND

In the field of display technology, a thin film transistor (TFT) array substrate is an important part of a display panel, and a manufacturing process of the TFT array substrate involves use of multi-channel photo mask. As a result, the manufacturing process is complex and has high cost.

### SUMMARY

The present application provides an array substrate, a preparing method thereof, and a display panel, so as to reduce the number of photomasks used in a manufacturing process of a thin film transistor array substrate and reduce the cost.

In order to solve the above problems, technical solutions provided by the present application are as follows:

The present application provides an array substrate, the array substrate including:
a substrate;
a first conductive layer provided on a side of the substrate; where the first conductive layer includes a source and a light-shielding electrode disposed apart from each other;
an active layer provided on a side of the first conductive layer away from the substrate; where the active layer includes a channel portion, a source contact portion, and a drain contact portion; the channel portion is connected between the source contact portion and the drain contact portion; and in a thickness direction of the array substrate, the channel portion is provided corresponding to the light-shielding electrode, and the source contact portion is connected to the source;
a second conductive layer provided on a side of the active layer away from the substrate, where the second conductive layer includes a gate provided corresponding to the channel portion; and
a third conductive layer provided on a side of the second conductive layer away from the substrate, where the third conductive layer includes a pixel electrode connected to the drain contact portion; and
where at least one of the first conductive layer and the second conductive layer further includes a common electrode disposed corresponding to the pixel electrode.

In the array substrate provided by the embodiment of the present application, at least one of the first conductive layer and the second conductive layer at least further includes a transparent conductive sub-layer, and the transparent conductive sub-layer forms the common electrode.

In the array substrate provided by the embodiment of the present application, a material of the transparent conductive sub-layer comprises indium tin oxide.

In the array substrate provided by the embodiment of the present application, the second conductive layer comprises the transparent conductive sub-layer, and the transparent conductive sub-layer further forms the gate.

In the array substrate provided by the embodiment of the present application, the second conductive layer further comprises one or more metal sub-layers disposed on a side of the transparent conductive sub-layer away from the substrate, and the metal sub-layer and the transparent conductive sub-layer form the gate.

In the array substrate provided by the embodiment of the present application, the first conductive layer comprises the transparent conductive sub-layer and one or more metal sub-layers disposed on a side of the transparent conductive sub-layer away from the substrate, and the metal sub-layer and the transparent conductive sub-layer form the source and the light-shielding electrode.

In the array substrate provided by the embodiment of the present application, a distance between the gate and the substrate is larger than a distance between the common electrode and the substrate in a thickness direction of the array substrate.

In the array substrate provided by the embodiment of the present application, the array substrate further including:
a first insulating layer located between the substrate and the first conductive layer; where a first via hole is disposed in a position of the first insulating layer corresponding to the source, and the source contact portion is connected to the source through the first via hole;
a second insulating layer located between the active layer and the second conductive layer, where the second insulating layer includes a first insulating portion disposed corresponding to the gate; and
a third insulating layer located between the second conductive layer and the third conductive layer, where a second via is disposed in a position of the third insulating layer corresponding to the drain contact, and the pixel electrode is connected to the drain contact portion through the second via.

The present application further provides a preparing method for an array substrate, including:
providing a substrate on a side of which a first conductive layer is prepared, where the first conductive layer includes a source and a light-shielding electrode disposed apart from each other;
preparing an active layer on a side of the first conductive layer away from the substrate, and where a part of the active layer is connected to the source;
preparing a second conductive layer on a side of the active layer away from the substrate of which a gate is included, and conducting the active layer with the gate as shields to form a channel portion, a source contact portion, and a drain contact portion; where the gate is provided corresponding to a part of the active layer, the second conductive layer further comprises a common electrode provided spaced apart from the gate, and the channel portion is connected between the source contact portion and the drain contact portion; and in a thickness direction of the array substrate, the channel portion is provided correspondingly to the light-shielding electrode, and the source contact portion is connected to the source; and
preparing a third conductive layer on a side of the second conductive layer away from the substrate, where the third conductive layer comprises a pixel electrode connected to the drain contact portion, and the pixel electrode is disposed corresponding to the common electrode.

Embodiments of the present application further provides a display panel including the array substrate according to one of the preceding embodiments.

The beneficial effects of the present application are: the array substrate includes a substrate, a first conductive layer, an active layer, a second conductive layer, and a third conductive layer all provided on the substrate, a source contact portion of the active layer is connected to a source of the first conductive layer, the second conductive layer includes a gate provided corresponding to a channel portion, a pixel electrode of the third conductive layer is connected to a drain contact portion of the active layer, and at least one of the first conductive layer and the second conductive layer further includes a common electrode provided corresponding to the pixel electrode. As described above, by disposing the source and the light-shielding electrode in the same layer, and disposing the common electrode in the same layer as at least one of the gate and the light-shielding electrode, the number of photomasks to be used can be reduced and the cost can be reduced.

### BRIEF DESCRIPTION OF THE DRAWINGS

In order to more clearly explain the technical solutions in embodiments of the present application, accompanying drawings that need to be used in the description of the embodiments will be briefly introduced below, and it is obvious that the accompanying drawings in following description are only some embodiments of the present application, and for those skilled in the art, other accompanying drawings can be obtained from these accompanying drawings without making creative labor.

FIG. 1 is a schematic diagram of an array substrate according to an embodiment of the present application.

FIG. 2 is a schematic diagram of a cross-sectional structure of an array substrate provided by an embodiment of the present application.

FIG. 3 is a schematic diagram of another cross-sectional structure of an array substrate provided by an embodiment of the present application.

FIG. 4 is a schematic diagram of yet another cross-sectional structural of an array substrate provided by an embodiment of the present application.

FIG. 5 is a flow schematic diagram of a preparing method of an array substrate according to an embodiment of the present application.

FIGS. 6A to 6F are schematic diagrams of film layer structures prepared in each step of preparing the array substrate in FIG. 2 using the preparing method of the array substrate in FIG. 5.

FIGS. 7A to 7F are schematic diagrams of film layer structures d prepared by each step of preparing the array substrate in FIG. 3 using the preparing method of the array substrate in FIG. 5.

FIG. 8 is another flow schematic diagram of an array substrate preparation method according to an embodiment of the present application.

FIGS. 9A to 9F are schematic diagrams of film layers prepared by each step of preparing the array substrate in FIG. 4 by the array substrate preparation method in FIG. 8.

### DETAILED DESCRIPTION OF EMBODIMENTS

The following description of each embodiment is made with reference to the accompanying drawings to illustrate specific embodiments in which the present application may be practiced. References to directional terms in the present application, such as “top”, “bottom”, “front”, “back”, “left”, “right”, “inner”, “outer”, “side”, etc., are merely directions with reference to the appended drawings. Accordingly, the directional terms used are intended to illustrate and understand the present application, and are not intended to limit the present application. In the accompanying drawings, structurally similar units are denoted by the same reference numerals. In the accompanying drawings, thicknesses of some layers and regions are exaggerated for clarity of understanding and ease of description. That means, dimensions and thicknesses of each component shown in the accompanying drawings are arbitrarily shown, but the present application is not limited thereto.

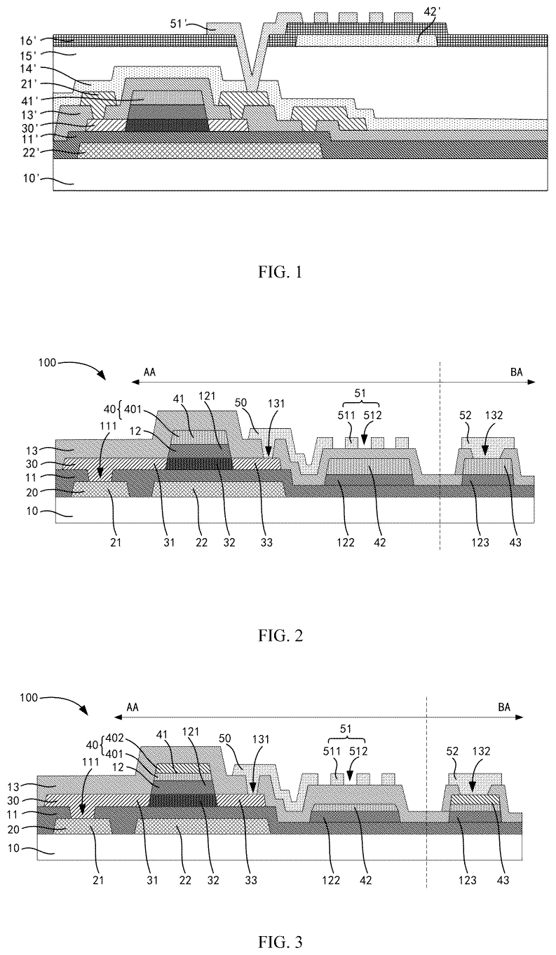

Referring to FIG. 1, an array substrate according to an embodiment of the present application is provided. The array substrate includes a substrate 10′, a light-shielding electrode 21′, an active layer 30′, a gate 41′, a source 22′, a drain, a common electrode 42′, and a pixel electrode 51′. The light-shielding electrode 21′, the active layer 30′, the gate 41′, the source 22′, the drain, the common electrode 42′, and the pixel electrode 51′ are all disposed on the substrate 10′. A first insulating layer 11′ is provided between the light-shielding electrode 21′ and the active layer 30′. A second insulating layer 12′ is provided between the active layer 30′ and the gate 41′. The active layer 30′ includes a channel portion, a source contact portion, and a drain contact portion. The channel portion is located between the source contact portion and the drain contact portion. Both the gate 41′ and the second insulating layer 12′ are provided corresponding to the channel portion. A third insulating layer 13′ is provided between the gate 41′, and the source 22′, the drain. The source 22′ is connected to the source contact portion through a via on the third insulating layer 13′. The drain is connected to the drain contact portion through a via on the third insulating layer 13′. A passivation layer 14′ and a flat layer 15′ are provided between the source 22′, the drain, and the common electrode 42′. A fourth insulating layer 16′ is provided between the common electrode 42′ and the pixel electrode 51′. The pixel electrode 51′ is connected to the drain through vias in the fourth insulating layer 16′, the flat layer 15′, and the passivation layer 14′.

In the array substrate shown in FIG. 1, the light-shielding electrode 21′ needs a photomask, the active layer 30′ needs a photomask, the gate 41′ and the first insulating layer 11′ need a photomask, the second insulating layer 12′ needs a photomask, the source 22′ and the drain need a photomask, the passivation layer 14′ needs a photomask, the flat layer 15′ needs a photomask, the common electrode 42′ needs a photomask, the fourth insulating layer 16′ needs a photomask, and the pixel electrode 51′ needs a photomask. In this way, a total of 10 photomasks are required for preparing the array substrate as shown in FIG. 1, resulting in a complicated preparing process and high cost.

Therefore, the present application provides a following array substrate, a preparing method thereof, and a display panel.

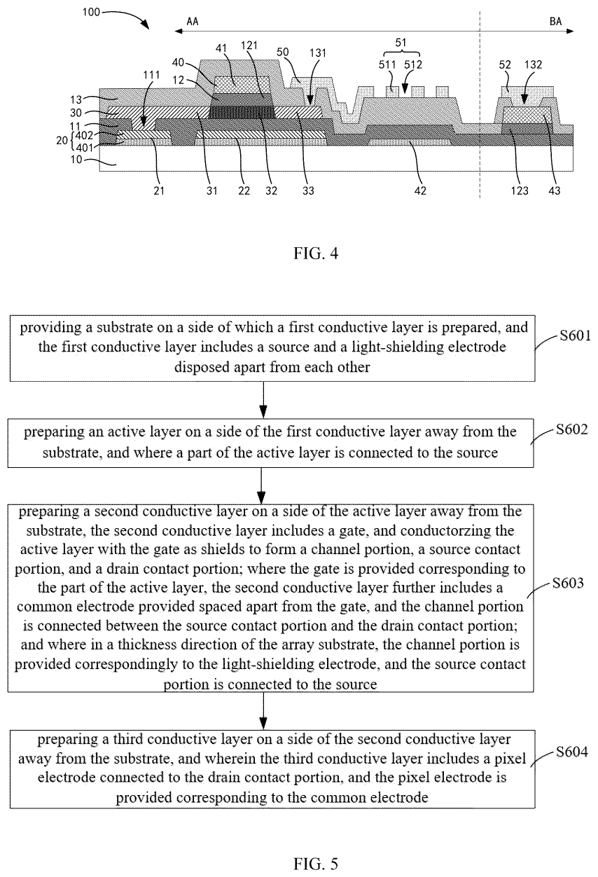

Referring to FIGS. 1 and 2, FIG. 2 is a schematic diagram of a cross-sectional structure of an array substrate provided by an embodiment of the present application. The array substrate 100 includes a substrate 10, a first conductive layer 20, an active layer 30, a second conductive layer 40, and a third conductive layer 50. The first conductive layer 20, the active layer 30, the second conductive layer 40, and the third conductive layer 50 are all disposed on the substrate 10. The first conductive layer 20 is provided on a side of the substrate 10. The first conductive layer 20 includes a source 21 and a light-shielding electrode 22 disposed apart from each other. The active layer 30 is provided on a side of the first conductive layer 20 away from the substrate 10. The active layer 30 includes a channel portion 32, a source contact portion 31, and a drain contact portion 33. The channel portion 32 is connected between the source contact portion 31 and the drain contact portion 33.

In a thickness direction of the array substrate 100, the channel portion 32 is provided corresponding to the light-shielding electrode 22. The source contact portion 31 is connected to the source 21. The second conductive layer 40 is provided on a side of the active layer 30 away from the substrate 10. The second conductive layer 40 includes a gate 41 provided corresponding to the channel portion 32. The third conductive layer 50 is provided on a side of the second conductive layer 40 away from the substrate 10. The third conductive layer 50 includes a pixel electrode 51 connected to the drain contact portion 33. At least one of the first conductive layer 20 and the second conductive layer 40 further includes a common electrode 42 disposed corresponding to the pixel electrode 51. In case where the common electrode 42 is formed of the first conductive layer 20, and the common electrode 42 is provided in the same layer as the light-shielding electrode 22. In case where the common electrode 42 is formed of the second conductive layer 40, and the common electrode 42 is provided in the same layer as the gate 41.

Optionally, at least one of the first conductive layer 20 and the second conductive layer 40 at least further includes a transparent conductive sub-layer 401. The transparent conductive sub-layer 401 forms the common electrode 42. That means, the common electrode 42 is formed of the transparent conductive sub-layer 401 in at least one of the first conductive layer 20 and the second conductive layer 40. So that the common electrode 42 can transmit light and conduct electricity. A material of the transparent conductive sub-layer 401 includes a transparent conductive material, such as indium tin oxide (ITO).

In the present embodiment, the source 21 and the light-shielding electrode 22 are provided in a same layer. The common electrode 42 is provided in a same layer as at least one of the gate 41 and the light-shielding electrode 22. The source 21 and the light-shielding electrode 22 can be formed using a same photomask, and the common electrode 42 and at least one of the gate 41 and the light-shielding electrode 22 can be formed using a same photomask, thereby reducing the number of photomasks to be used and reducing the cost.

In one embodiment, referring to FIG. 1, the second conductive layer 40 includes the transparent conductive sub-layer 401. The transparent conductive sub-layer 401 further forms the gate 41. That means, the gate 41 and the common electrode 42 disposed apart from the gate 41 are formed in the transparent conductive sub-layer 401.

Specifically, referring to FIG. 1, the array substrate 100 further includes transistors disposed on the substrate 10. The transistor may be a thin film transistor. The transistor includes the source 21, the active layer 30, and the gate 41. The active layer 30 is provided on the side of the source 21 away from the substrate 10. The gate 41 is provided on the side of the active layer 30 away from the substrate 10. The active layer 30 includes the channel portion 32 and the source contact portion 31 located on the side of the channel portion 32. Needless to say, the active layer 30 further includes the drain contact portion 33 located on the side of the channel portion 32 away from the source contact portion 31. That means, the drain contact portion 33 and the source contact portion 31 are located on opposite sides of the channel portion 32. The channel portion 32 is connected between the source contact portion 31 and the drain contact portion 33. The gate 41 is disposed corresponding to the channel portion 32. An orthographic projection of the gate 41 on the substrate 10 coincides with an orthographic projection of the channel portion 32 on the substrate 10.

Optionally, the substrate 10 may be a rigid substrate or a flexible substrate. If the substrate 10 is a rigid substrate, it may include a rigid substrate such as a glass substrate, a quartz substrate, or a silicon wafer. If the substrate 10 is a flexible substrate, the substrate 10 may include a flexible substrate such as a Polyimide (PI) film or an ultra-thin glass film. If the substrate 10 is a polyimide substrate, moisture or oxygen may penetrate into the substrate 10 more easily than a glass substrate. In order to prevent this, a buffer layer having a single-layer or multi-layer structure including silicon oxide or silicon nitride may be provided on the substrate 10.

The first conductive layer 20 is provided on the substrate 10. The first conductive layer 20 includes a source 21 and a light-shielding electrode 22 disposed apart from each other and insulated from each other. The light-shielding electrode 22 is provided corresponding to at least the channel portion 32 to shield light from the channel portion 32 and reduce a photo-generated leakage current of the transistor. A material of the first conductive layer 20 includes a material having low resistance and light-shielding properties, such as Al, Ti, Mo, Cu, Ni, or an alloy thereof.

The array substrate 100 further includes a first insulating layer 11 located between the first conductive layer 20 and the active layer 30. The first insulating layer 11 covers the first conductive layer 20 and the substrate 10. A first via hole 111 is disposed at a position of the first insulating layer 11 corresponding to the source 21. The first via hole 111 penetrates the first insulating layer 11 and exposes at least a part of the source 21. The source contact portion 31 is connected to the source 21 through the first via hole 111. That means, a part of the source contact portion 31 is located in the first via hole 111 and connected to the source 21.

A film thickness of the first insulating layer 11 is ranged from 3000 angstroms to 5000 angstroms, such as 3000 angstroms, 3500 angstroms, 4000 angstroms, 4500 angstroms, 5000 angstroms, or the like. A material of the first insulating layer 11 includes an inorganic material. For example, the first insulating layer 11 may be a plurality of layers or a single layer including at least one of tetraethyl orthosilicate, silicon nitride, silicon oxide, and the like.

The active layer 30 is provided on a side of the first insulating layer 11 away from the substrate 10. Both the source contact portion 31 and the drain contact portion 33 of the active layer 30 are formed by conductorizing a semiconductor material which forms the active layer 30. The source contact portion 31 and the drain contact portion 33 of the active layer 30 form a conductor. The source contact portion 31 is located on a part of the first insulating layer 11 and in the first via hole 111. The source contact portion 31 located in the first via hole 111 covers a hole wall of the first via hole 111 and the source 21 exposed by the first via hole 111 to be connected to the source 21.

A film thickness of the active layer 30 is ranged from 100 angstroms to 500 angstroms, such as 100 angstroms, 200 angstroms, 220 angstroms, 250 angstroms, 280 angstroms, 300 angstroms, 350 angstroms, 380 angstroms, 400 angstroms, 500 angstroms, etc. The material of the active layer 30 includes a semiconductor material such as polysilicon or a metal oxide.

The array substrate 100 further includes a second insulating layer 12 located between the active layer 30 and the gate 41. The second insulating layer 12 is provided on a side of the active layer 30 away from the substrate 10 and provided corresponding to the channel portion 32. A material of the second insulating layer 12 includes an inorganic material. For example, the second insulating layer 12 may be a plurality of layers or a single layer including at least one of tetraethyl orthosilicate, silicon nitride, silicon oxide, and the like.

The second conductive layer 40 is provided on a side of the second insulating layer 12 away from the substrate 10. The second conductive layer 40 includes a gate 41 of the transistor. The gate 41 is provided corresponding to the second insulating layer 12. The second conductive layer 40 further includes a common electrode 42 disposed at an interval from the gate 41. The common electrode 42 is disposed in the same layer as the gate 41. The second insulating layer 12 includes a first insulating portion 121 provided corresponding to the gate 41 and a second insulating portion 122 provided corresponding to the common electrode 42. In the thickness direction of the array substrate 100, a distance between the gate 41 and the substrate 10 is larger than a distance between the common electrode 42 and the substrate 10.

It should be noted that the term “disposed in the same layer” in the present application means that at least two different structures are obtained in the same layer by patterning a film layer formed of the same material in a preparation process. For example, in the present embodiment, if the gate 41 and the common electrode 42 are obtained by patterning the same transparent conductive sub-layer 401 the gate 41 and the common electrode 42 are provided in the same layer.

Optionally, if the material of the transparent conductive sub-layer 401 is indium tin oxide, the gate 41 and the common electrode 42 can be deposited by a process such as magnetron sputtering and vacuum evaporation or the like. So that a deposition by a physical vapor deposition method is not necessary, and the number of machines required for the physical vapor deposition process can be reduced, thus, the number of machines required for the physical vapor deposition process can be reduced while reducing the number of photomasks used and reducing the cost.

As described above, since the source 21 and the light-shielding electrode 22 are provided in the same layer, and the common electrode 42 and the gate 41 are provided in the same layer, the source 21 and the light-shielding electrode 22 can be formed using the same photomask, and the gate 41 and the common electrode 42 can be formed using the same photomask, thereby reducing the number of photomasks to be used and reducing the cost.

The array substrate 100 further includes a third insulating layer 13 located between the second conductive layer 40 and the third conductive layer 50. A second via hole 131 is disposed at a position of the third insulating layer 13 corresponding to the drain contact portion 33. The pixel electrode 51 is connected to the drain contact portion 33 through the second via hole 131. That means, a part of the pixel electrode 51 is located in the second via hole 131 and connected to the drain contact portion 33. The third insulating layer 13 covers a portion of the first insulating layer 11, a portion of the active layer 30, the gate 41, and the common electrode 42.

More specifically, the third insulating layer 13 covers an upper surface and a sidewall of the gate 41, a sidewall of the first insulating portion 121, an upper surface and a sidewall of the source contact portion 31, an upper surface and a sidewall of the drain contact portion 33, an upper surface and a sidewall of the common electrode 42, a sidewall of the second insulating portion 122, and a portion of the first insulating layer 11.

A material of the third insulating layer 13 includes an inorganic material. For example, the third insulating layer 13 may be a plurality of layers or a single layer including at least one of tetraethyl orthosilicate, silicon nitride, silicon oxide, and the like.

For convenience of description, the present application defines that a surface of a side of each structure away from the substrate 10 is an upper surface, a surface corresponding to the upper surface is a lower surface, and a side wall connecting the upper surface and the lower surface is a side wall. For example, the surface of a side of the gate 41 away from the substrate 10 is the upper surface of the gate 41, a surface corresponding to the upper surface of the gate 41 is the lower surface of the gate 41, the lower surface of the gate 41 is in contact with the first insulating portion 121, and a side wall connecting the upper surface and the lower surface of the gate 41 is the side wall of the gate 41.

The pixel electrode 51 is provided on a side of the third insulating layer 13 away from the substrate 10. The third insulating layer 13 is provided with the second via hole 131 at a position corresponding to the drain contact portion 33. The second via hole 131 penetrates the third insulating layer 13 and exposes at least a part of the drain contact portion 33. A portion of the pixel electrode 51 is located in the second via hole 131, and is connected to the drain contact portion 33 exposed by the second via hole 131. The pixel electrode 51 includes a plurality of electrode portions 511. A slit 512 is provided between adjacent two electrode portions 511. A material of the pixel electrode 51 includes a transparent conductive material, such as indium tin oxide (ITO), indium zinc oxide (IZO), zinc oxide (ZnO), or indium oxide (In₂O₃).

In this embodiment, the source 21 and the light-shielding electrode 22 require a photomask. The first insulating layer 11 requires a photomask. The active layer 30 requires a photomask. The second insulating layer 12, the gate 41, and the common electrode 42 require a photomask. The third insulating layer 13 requires a photomask. The pixel electrode 51 requires a photomask. So that a total of 6 photomasks are required to form the array substrate 100 of the present application.

Compared with the array substrate requiring 10 photomasks of the example of FIG. 1, the array substrate 100 of the example of FIG. 2 only requires 6 photomasks, which reduces the number of photomasks used and thus reduces the cost. Furthermore, in case where preparing the gate 41 and the common electrode 42, the gate 41 and the common electrode 42 can be deposited by magnetron sputtering, vacuum vapor deposition or the like, so that a deposition by a physical vapor deposition method is not necessary, and the number of machines required for the physical vapor deposition process can be reduced, and the number of machines required for the physical vapor deposition process can be reduced while reducing the number of photomasks to be used to further reduce the cost.

In one embodiment, continuing to refer to FIG. 2, the array substrate 100 includes a display area AA and a bonding area BA located on a side of the display area AA. The display area AA is used for displaying a screen. The bonding area BA is used for bonding a driver chip, a flexible circuit board, or the like. The source 21, the light-shielding electrode 22, the active layer 30, the gate 41, the common electrode 42, and the pixel electrode 51 are all located in the display area AA.

The second conductive layer 40 further includes a signal line 43 located in the bonding area BA. The second insulating layer 12 further includes a third insulating portion 123 provided corresponding to the signal line 43. The third conductive layer 50 further includes a bonding terminal 52 located in the bonding area BA. A third via hole 132 is disposed at a position of the third insulating layer 13 corresponding to the signal line 43. A part of the bonding terminal 52 is located in the third via hole 132 and connected to the signal line 43. The third insulating layer 13 also covers a portion of an upper surface and a side wall of the signal line 43 and a side wall of the third insulating portion 123.

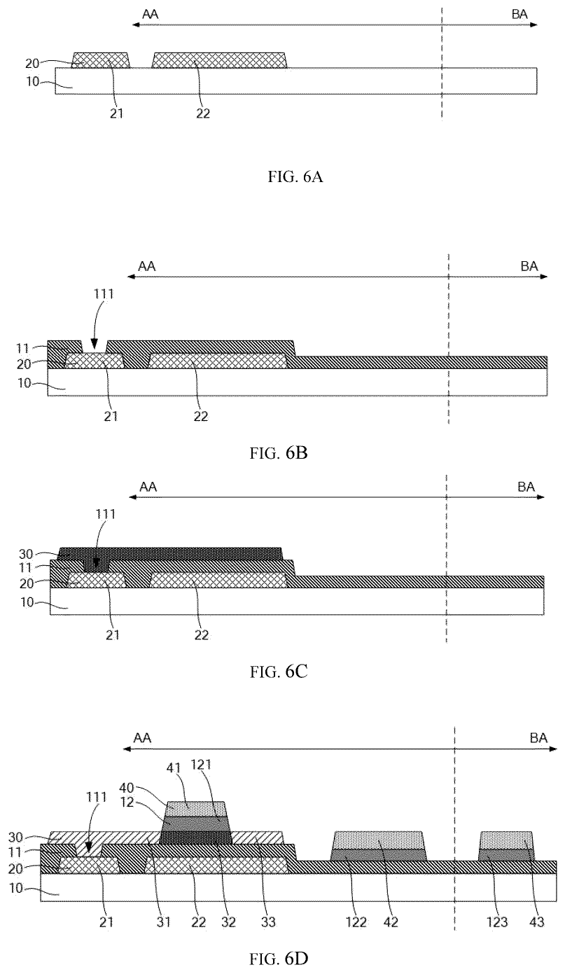

In one embodiment, referring to FIGS. 1 to 3, FIG. 3 is a schematic diagram of another cross-sectional structure of an array substrate provided by an embodiment of the present application. Referring to FIG. 3, the second conductive layer 40 in the embodiment illustrated in FIG. 3 is different from that illustrated in FIG. 2, the second conductive layer 40 further includes one or more metal sub-layer 402 disposed on a side of the transparent conductive sub-layer 401 away from the substrate 10. The metal sub-layer 402 and the transparent conductive sub-layer 401 form the gate 41. The transparent conductive sub-layer 401 is a top film layer of the common electrode 42. That means, the common electrode 42 is formed of the transparent conductive sub-layer 401 and does not include the metal sub-layer 402.

Specifically, the second conductive layer 40 includes the transparent conductive sub-layer 401 and the one or more metal sub-layers 402. The number of the metal sub-layers 402 may be multiple, for example, the second conductive layer 40 includes two metal sub-layers 402. A material of the first metal sub-layer is copper, a material of the second metal sub-layer is molybdenum, titanium, or molybdenum-titanium alloy, and the first metal sub-layer is located between the second metal sub-layer and the transparent conductive sub-layer 401, so that the second conductive layer 40 can be formed by stacking three sub-layers.

The transparent conductive sub-layer 401 and the metal sub-layer 402 together form the gate 41. The transparent conductive sub-layer 401 forms the common electrode 42. The metal sub-layer 402 does not form the common electrode 42. That means, the gate 41 is formed of the transparent conductive sub-layer 401 and the metal sub-layer 402, and the common electrode 42 is formed of the transparent conductive sub-layer 401. In other words, the gate 41 is formed of a plurality of sub-layers, and the common electrode 42 is formed of a single sub-layer.

Optionally, the second conductive layer 40 is subjected to a yellow light process using a half-tone mask (HTM) to form the gate 41 and the common electrode 42. Specifically, the transparent conductive sub-layer 401 and the metal sub-layer 402 are subjected to a yellow light process using the halftone photomask. The process includes: the transparent electron-conducting layer 401 and the metal sublayer 402 are etched for a first time to form a gate pattern and a common electrode pattern, at this moment, the gate pattern and the common electrode pattern both include the transparent conductive sub-layer 401 and the metal sub-layer 402; and then, the gate pattern and a common electrode pattern are etched for a second etching to form the gate 41; and at the same time, the metal sub-layer 402 in the common electrode pattern is removed and the transparent conductive layer 401 is exposed to form the common electrode 42. Please refer to the above-described embodiments for other descriptions, and will not be repeated here.

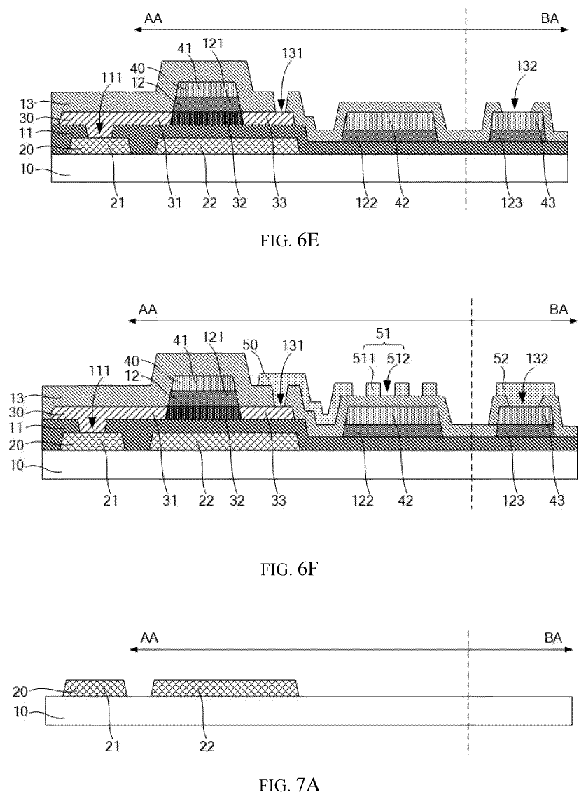

In one embodiment, referring to FIGS. 1 to 4, FIG. 4 is a schematic diagram of yet another cross-sectional structural of an array substrate provided by an embodiment of the present application. Referring to FIG. 4, a difference from the embodiment illustrated in FIG. 3 is that: the common electrode 42 is provided in the same layer as the light-shielding electrode 22. That means, the common electrode 42 is formed of the first conductive layer 20.

Specifically, the first conductive layer 20 includes the transparent conductive sub-layer 401 and the one or more metal sub-layers 402 disposed on a side of the transparent conductive sub-layer 401 away from the substrate 10. The metal sub-layer 402 and the transparent conductive sub-layer 401 form the source 21 and the light-shielding electrode 22, and the transparent conductive sub-layer 401 is a top film layer of the common electrode 42.

Optionally, the number of the metal sub-layers 402 may be multiple, for example, the first conductive layer 20 includes two layers of the metal sub-layers 402. A material of the first metal sub-layer is copper. A material of the second metal sub-layer is molybdenum, titanium, or a molybdenum-titanium alloy. The first metal sub-layer is located between the second metal sub-layer and the transparent conductive sub-layer 401. So that the first conductive layer 20 can be formed by stacking three sub-layers.

The transparent conductive sub-layer 401 and the metal sub-layer 402 together form the source 21 and the light-shielding electrode 22. The transparent conductive sub-layer 401 forms the common electrode 42. The metal sub-layer 402 does not form the common electrode 42. That means, the source 21 and the light-shielding electrode 22 are formed by the transparent conductive sub-layer 401 and the metal sub-layer 402, and the common electrode 42 is formed by the transparent conductive sub-layer 401. In other words, the source 21 and the light-shielding electrode 22 are formed by multilayer sub-layers, and the common electrode 42 is formed by a single sub-layer.

Optionally, a halftone photomask is used to perform a yellow light process on the first conductive layer 20 to form the source 21, the light-shielding electrode 22, and the common electrode 42. Specifically, the transparent conductive sub-layer 401 and the metal sub-layer 402 are subjected to a yellow light process using a halftone photomask. The process includes: the transparent electron-conducting layer 401 and the metal sublayer 402 are etched for a first time to form a source pattern, a light-shielding electrode pattern, and a common electrode pattern; and at this moment, the source pattern, the light-shielding electrode pattern, and the common electrode pattern all include the transparent conductive sub-layer 401 and the metal sub-layer 402; and then the source pattern, the light-shielding electrode pattern, and the common electrode pattern are etched for a second time to form the source 21 and the light-shielding electrode 22, and at the same time, the metal sub-layer 402 in the common electrode pattern is removed, and the transparent conductive sub-layer 401 is exposed to form the common electrode 42. Please refer to the above-described embodiments for other descriptions, and will not be repeated here.

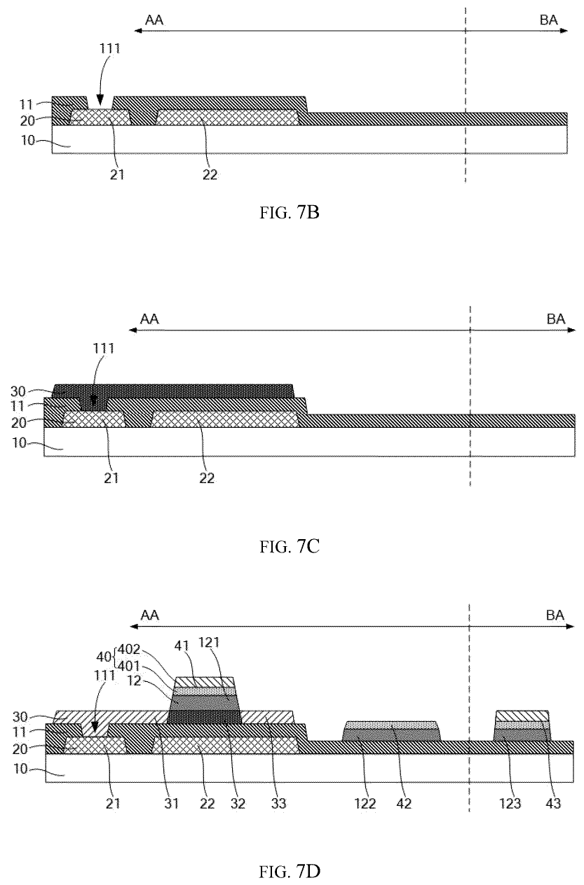

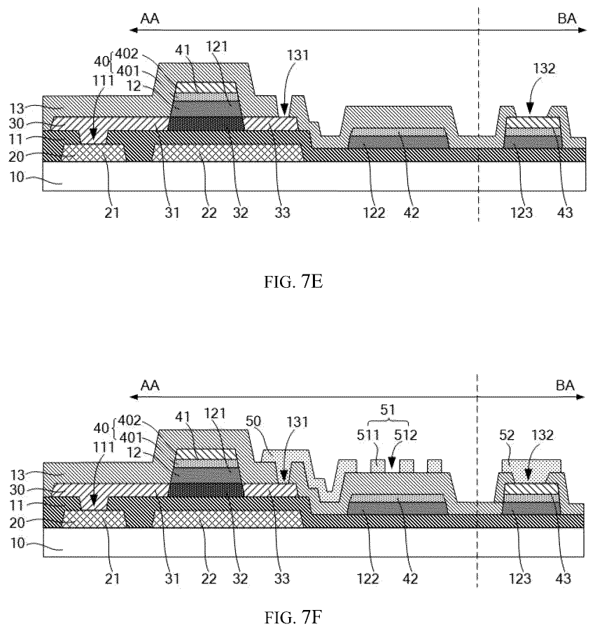

In one embodiment, the embodiment of the present application further provides a preparing method for an array substrate. Referring to FIGS. 1 to 6F, FIG. 5 is a flow schematic diagram of a preparing method of an array substrate according to an embodiment of the present application. FIGS. 6A to 6F are schematic diagrams of film layer structures prepared in each step of preparing the array substrate in FIG. 2 using the preparing method of the array substrate in FIG. 5. Referring to FIG. 5, the preparing method includes the following steps:

S601: providing a substrate 10 on a side of which a first conductive layer 20 is prepared, and the first conductive layer 20 includes a source 21 and a light-shielding electrode 22 disposed apart from each other.

Specifically, referring to FIG. 6A, the substrate 10 is provided. The substrate 10 is divided into a display area AA and a bonding area BA located on a side of the display area AA. A first conductive film is deposited on the substrate 10. A first photomask is used to perform a yellow light process on the first conductive film to form the first conductive layer 20. The first conductive layer 20 includes a source 21 and a light-shielding electrode 22 arranged apart from each other. The material of the first conductive layer 20 includes a material having low resistance and light shielding properties such as Al, Ti, Mo, Cu, Ni, or an alloy thereof.

S602: preparing an active layer 30 on a side of the first conductive layer 20 away from the substrate 10, and where a part of the active layer 30 is connected to the source 21.

Specifically, referring to FIG. 6B, a first insulating film is deposited on the first conductive layer 20 and the substrate 10. A yellow light process is performed on the first insulating film using a second photomask to form the first insulating layer 11. A first via hole 111 is formed at a position of the first insulating layer 11 corresponding to the source 21.

Referring to FIG. 6C, a semiconductor thin film is deposited on the first insulating layer 11, and a yellow light process is performed on the semiconductor thin film using a third photomask to form the active layer 30. Apart of the active layer 30 is connected to the source 21 through the first via hole 111.

S603: preparing a second conductive layer 40 on a side of the active layer 30 away from the substrate 10, the second conductive layer 40 includes a gate 41, and conductorizing the active layer 30 with the gate 41 as shields to form a channel portion 32, a source contact portion 31, and a drain contact portion 33; where the gate 41 is provided corresponding to the part of the active layer, the second conductive layer 40 further includes a common electrode 42 provided spaced apart from the gate 41, and the channel portion 32 is connected between the source contact portion 31 and the drain contact portion 33; and in a thickness direction of the array substrate 100, the channel portion 32 is provided corresponding to the light-shielding electrode 22, and the source contact portion 31 is connected to the source 21.

Specifically, referring to FIG. 6D, a second insulating film and a transparent conductive sub-layer are deposited on the active layer 30. A yellow light process is performed on the second insulating film and the transparent conductive sub-layer using a fourth photomask to form the second insulating layer 12 and the second electron-conductive layer 40. The material of the transparent conductive sub-layer includes indium tin oxide or the like. The second conductive layer 40 includes the gate 41 provided corresponding to the channel portion 32 and the common electrode 42 provided spaced apart from the gate 41. The second insulating layer 12 includes the first insulating portion 121 provided corresponding to the gate 41 and the second insulating portion 122 provided corresponding to the common electrode 42.

The active layer 30 is conductorized with the gate electrode 41 and the first insulating portion 121 as shields. The active layer 30 forms the channel portion 32, the source contact portion 31, and the drain contact portion 33. The channel portion 32 is connected between the source contact portion 31 and the drain contact portion 32. In the thickness direction of the array substrate 100, the channel portion 32 is provided corresponding to the light-shielding electrode 22, and the source contact portion 31 is connected to the source 21.

S604: preparing a third conductive layer 50 on a side of the second conductive layer 40 away from the substrate 10, and wherein the third conductive layer 50 includes a pixel electrode 51 connected to the drain contact portion 33, and the pixel electrode 51 is provided corresponding to the common electrode 42.

Referring to FIG. 6E, a third insulating film is deposited on the gate 41, and a yellow light process is performed on the third insulating film using a fifth photomask to form the third insulating layer 13. A second via hole 131 is disposed at a position of the third insulating layer 13 corresponding to the drain contact portion 33. The second via hole 131 penetrates the third insulating layer 13 and exposes at least a part of the drain contact portion 33.

Referring to FIG. 6F, a second conductive film is deposited on the third insulating layer 13, and a yellow light process is performed on the second conductive film using a sixth photomask to form the third conductive layer 50. The third conductive layer 50 includes a pixel electrode 51 connected to the drain contact portion 33, and the pixel electrode 51 is provided corresponding to the common electrode 42.

As described above, in the preparing method of the array substrate of the present embodiment, a total of 6 photomasks are required to form the array substrate 100 of the present application. Compared with the array substrate 100 of the example of FIG. 1, which requires 10 photomasks, the array substrate 100 of the example of FIG. 2 requires only 6 photomasks, which reduces the number of photomasks used and thus reduces the cost. Furthermore, in case where preparing the gate 41 and the common electrode 42, deposition by a process such as magnetron sputtering or vacuum vapor deposition can be adopted, so that deposition by a physical vapor deposition method can be skipped, and the number of machines required for the physical vapor deposition process can be reduced, and thus, the cost can be further reduced by reducing the number of machines required for the physical vapor deposition process while reducing the number of photomasks used and reducing the cost.

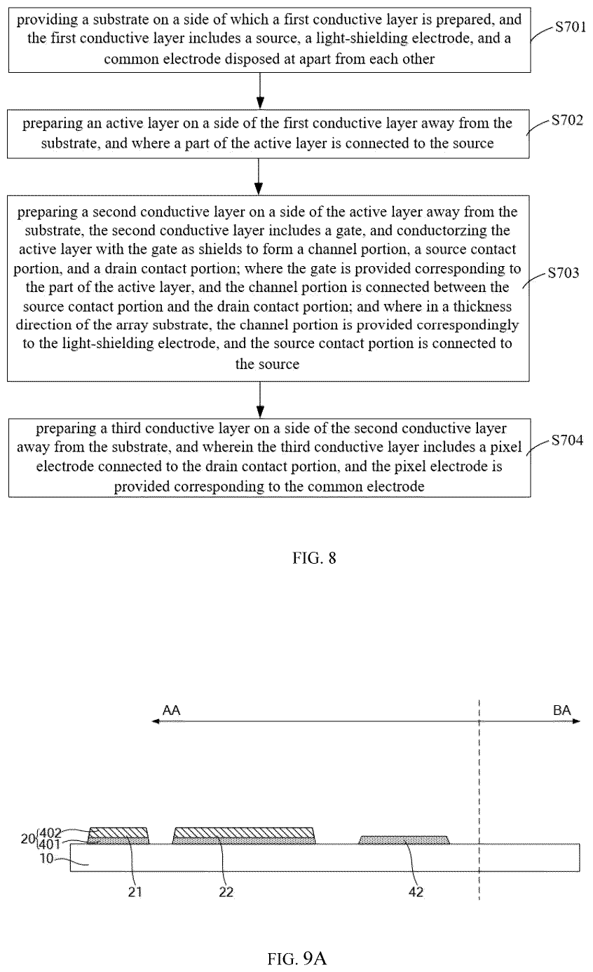

In one embodiment, referring to FIGS. 1 to 7F, FIGS. 7A to 7F are schematic diagrams of film layer structures d prepared by each step of preparing the array substrate in FIG. 3 using the preparing method of the array substrate in FIG. 5. Referring to FIG. 5 and FIG. 7A to FIG. 7F, the preparing method of the array substrate includes the following steps:

S601: providing a substrate 10 on a side of which a first conductive layer 20 is prepared, and the first conductive layer 20 includes a source 21 and a light-shielding electrode 22 disposed apart from each other.

Specifically, referring to FIG. 7A, the substrate 10 is provided. The substrate 10 is divided into a display area AA and a bonding area BA located on a side of the display area AA. A first conductive film is deposited on the substrate 10. A first photomask is used to perform a yellow light process on the first conductive film to form the first conductive layer 20. The first conductive layer 20 includes a source 21 and a light-shielding electrode 22 arranged apart from each other. The material of the first conductive layer 20 includes a material having low resistance and light shielding properties such as Al, Ti, Mo, Cu, Ni, or an alloy thereof.

S602: preparing an active layer 30 on a side of the first conductive layer 20 away from the substrate 10, and where a part of the active layer 30 is connected to the source 21.

Specifically, referring to FIG. 7B, a first insulating film is deposited on the first conductive layer 20 and the substrate 10. A yellow light process is performed on the first insulating film using a second photomask to form the first insulating layer 11. A first via hole 111 is formed at a position of the first insulating layer 11 corresponding to the source 21.

Referring to FIG. 7C, a semiconductor thin film is deposited on the first insulating layer 11, and a yellow light process is performed on the semiconductor thin film using a third photomask to form the active layer 30. Apart of the active layer 30 is connected to the source 21 through the first via hole 111.

S603: preparing a second conductive layer 40 on a side of the active layer 30 away from the substrate 10, the second conductive layer 40 includes a gate 41, and conductorizing the active layer 30 with the gate 41 as shields to form a channel portion 32, a source contact portion 31, and a drain contact portion 33; where the gate 41 is provided corresponding to the part of the active layer 30, the second conductive layer 40 further includes a common electrode 42 provided spaced apart from the gate 41, and the channel portion 32 is connected between the source contact portion 31 and the drain contact portion 33; and where in a thickness direction of the array substrate 100, the channel portion 32 is provided correspondingly to the light-shielding electrode 22, and the source contact portion 31 is connected to the source 21.

Specifically, referring to FIG. 7D, a second insulating film, the transparent conductive sub-layer 401, and the one or more metal sub-layers 402 are deposited on the active layer 30, successively. A yellow light process is performed on the second insulating film, the transparent conductive sub-layer 401, and the metal sub-layer 402 using a fourth photomask to form the second insulating layer 12 and the second electron-conductive layer 40. A material of the transparent conductive sub-layer 401 includes indium tin oxide or the like. The metal sub-layer is a layer formed of a material including molybdenum, titanium, copper, or a molybdenum-titanium alloy. The fourth photomask is a halftone photomask or the like.

The transparent conductive sub-layer 401 and the metal sub-layer 402 together form the gate 41, the transparent conductive sub-layer 401 forms the common electrode 42, and the metal sub-layer 402 does not form the common electrode 42. That means, the gate 41 is formed of the transparent conductive sub-layer 401 and the metal sub-layer 402, and the common electrode 42 is formed of the transparent conductive sub-layer 401. In other words, the gate 41 is formed of multiple sublayers, and the common electrode 42 is formed of a single sublayer.

Specifically, the transparent conductive sub-layer 401 and the metal sub-layer 402 are subjected to a yellow light process using a halftone photomask, which includes that: the transparent electron-conducting layer 401 and the metal sublayer 402 are etched for a first time to form a gate pattern and a common electrode pattern; and the gate pattern and the common electrode pattern all include the transparent conductive sub-layer 401 and the metal sub-layer 402; and then the gate pattern and the common electrode pattern are etched for a second time to form the gate, and at the same time, the metal sub-layer 402 in the common electrode pattern is removed, and the transparent conductive sub-layer 401 is exposed to form the common electrode 42.

The active layer 30 is conductorized with the gate electrode 41 and the first insulating portion 121 being shields. The active layer 30 forms the channel portion 32 connected between the source contact portion 31 and the drain contact portion 33. The channel portion 32 is provided corresponding to the light-shielding electrode 22 in the thickness direction of the array substrate 100. The source contact portion 31 is connected to the source electrode 21.

S604: preparing a third conductive layer 50 on a side of the second conductive layer 40 away from the substrate 10, and wherein the third conductive layer 50 includes a pixel electrode 51 connected to the drain contact portion 33, and the pixel electrode 51 is provided corresponding to the common electrode 42.

Referring to FIG. 7E, a third insulating film is deposited on the gate 41, and a yellow light process is performed on the third insulating film using a fifth photomask to form the third insulating layer 13. A second via hole 131 is disposed at a position of the third insulating layer 13 corresponding to the drain contact portion 33. The second via hole 131 penetrates the third insulating layer 13 and exposes at least a part of the drain contact portion 33.

Referring to FIG. 7F, the second conductive film is deposited on the third insulating layer 13, and a yellow light process is performed on the second conductive film using a sixth photomask to form the third conductive layer 50. The third conductive layer 50 includes a pixel electrode 51 connected to the drain contact portion 33, and the pixel electrode 51 is provided corresponding to the common electrode 42.

As described above, in the preparing method of the array substrate of the present embodiment, a total of 6 photomasks are required to form the array substrate 100 of the present application. Compared with the array substrate 100 of the example of FIG. 1, which requires 10 photomasks, the array substrate 100 of the example of FIG. 3 requires only 6 photomasks, which reduces the number of photomasks used and thus reduces the cost. Furthermore, in case where preparing the gate 41 and the common electrode 42, deposition by a process such as magnetron sputtering or vacuum vapor deposition can be adopted, so that deposition by a physical vapor deposition method can be skipped, and the number of machines required for the physical vapor deposition process can be reduced, and thus, the cost can be further reduced by reducing the number of machines required for the physical vapor deposition process while reducing the number of photomasks used and reducing the cost.

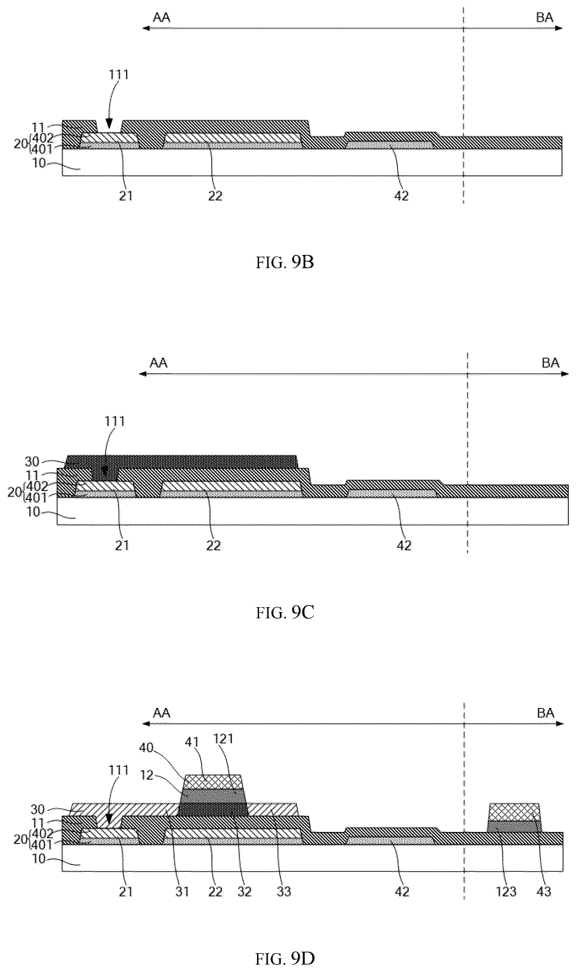

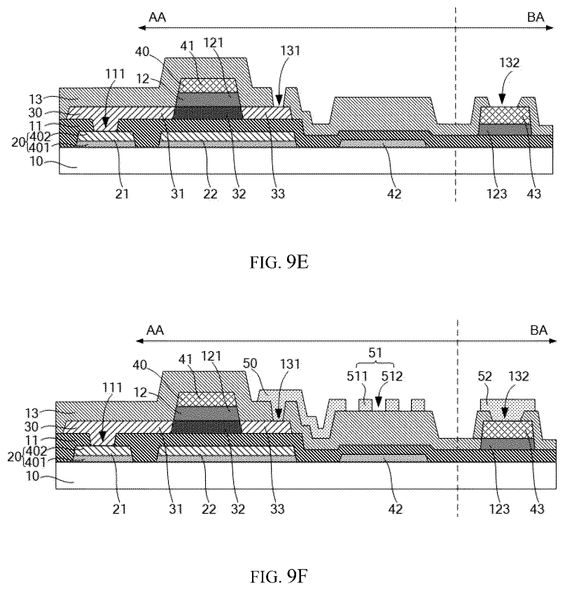

In one embodiment, referring to FIGS. 1 to 9F, FIG. 8 is another flow schematic diagram of an array substrate preparation method according to an embodiment of the present application. FIGS. 9A to 9F are are schematic diagrams of film layers prepared by each step of preparing the array substrate in FIG. 4 by the array substrate preparation method in FIG. 8. Referring to FIG. 8 and FIG. 9A to FIG. 9F, the preparing method of the array substrate includes the following steps:

S701: providing a substrate 10 on a side of which a first conductive layer 20 is prepared, and the first conductive layer 20 includes a source 21, a light-shielding electrode 22, and a common electrode 42 disposed apart from each other.

Specifically, referring to FIG. 9A, the substrate 10 is provided. The substrate 10 is divided into a display area AA and a bonding area BA located on one side of the display area AA. The transparent conductive sub-layer 401 and the one or more metal sub-layer 402 are deposited on the substrate 10, and a yellow light process is performed on the transparent conductive sub-layer 401 and the metal sub-layer 402 using a first photomask to form the second insulating layer 12 and the first conductive layer 20, where the material of the transparent conductive sub-layer 401 includes indium tin oxide or the like, and the material of the metal sublayer includes a single layer or a stack of molybdenum, titanium, copper or molybdenum titanium alloy. The first photomask is a halftone photomask or the like.

The transparent conductive sub-layer 401 and the metal sub-layer 402 together form the source 21 and the light-shielding electrode 22, the transparent conductive sub-layer 401 forms the common electrode 42, and the metal sub-layer 402 does not form the common electrode 42. That means, the source 21 and the light-shielding electrode 22 are formed of the transparent conductive sub-layer 401 and the metal sub-layer 402, and the common electrode 42 is formed of the transparent conductive sub-layer 401. In other words, the source 21 and the light-shielding electrode 22 are formed of multiple sublayers, and the common electrode 42 is formed of a single sublayer.

Specifically, the transparent conductive sub-layer 401 and the metal sub-layer 402 are subjected to a yellow light process using a halftone photomask. The process includes: the transparent electron-conducting layer 401 and the metal sublayer 402 are etched for a first time to form a source pattern, a light-shielding electrode pattern, and a common electrode pattern; and the source pattern, the light-shielding electrode pattern, and the common electrode pattern all include the transparent conductive sub-layer 401 and the metal sub-layer 402; and then the source pattern, the light-shielding electrode pattern, and the common electrode pattern are etched for a second time to form the source 21 and the light-shielding electrode 22, and at the same time, the metal sub-layer 402 in the common electrode pattern is removed, and the transparent conductive sub-layer 401 is exposed to form the common electrode 42.

S702: preparing an active layer 30 on a side of the first conductive layer 20 away from the substrate 10, and where a part of the active layer 30 is connected to the source 21.

Specifically, referring to FIG. 9B, a first insulating film is deposited on the first conductive layer 20 and the substrate 10. A yellow light process is performed on the first insulating film using a second photomask to form the first insulating layer 11. A first via hole 111 is formed at a position of the first insulating layer 11 corresponding to the source 21.

Referring to FIG. 9C, a semiconductor thin film is deposited on the first insulating layer 11, and a yellow light process is performed on the semiconductor thin film using a third photomask to form the active layer 30. Apart of the active layer 30 is connected to the source 21 through the first via hole 111.

S703: preparing a second conductive layer 40 on a side of the active layer 30 away from the substrate 10, the second conductive layer 40 includes a gate 41, and conductorizing the active layer 30 with the gate 41 as shields to form a channel portion 32, a source contact portion 31, and a drain contact portion 33; where the gate 41 is provided corresponding to the part of the active layer, and the channel portion 32 is connected between the source contact portion 31 and the drain contact portion 33; and where in a thickness direction of the array substrate 100, the channel portion 32 is provided corresponding to the light-shielding electrode 22, and the source contact portion 31 is connected to the source 21.

Specifically, referring to FIG. 9D, a second insulating film and a first conductive film are deposited on the active layer 30, and a yellow light process is performed on the second insulating film and the first conductive film using a fourth photomask to form the second insulating layer 12 and the second conductive layer 40. The material of the first conductive film includes copper, molybdenum, titanium, molybdenum-titanium alloy, etc. The second conductive layer 40 includes the gate 41 provided corresponding to the channel portion 32, and the second insulating layer 12 includes the first insulating portion 121 provided corresponding to the gate 41.

The active layer 30 is conductorized with the gate electrode 41 and the first insulating portion 121 as shields. The active layer 30 forms the channel portion 32, the source contact portion 31, and the drain contact portion 33. The channel portion 32 is connected between the source contact portion 31 and the drain contact portion 32. In the thickness direction of the array substrate 100, the channel portion 32 is provided corresponding to the light-shielding electrode 22, and the source contact portion 31 is connected to the source 21.

S704: preparing a third conductive layer 50 on a side of the second conductive layer 40 away from the substrate 10, and wherein the third conductive layer 50 includes a pixel electrode 51 connected to the drain contact portion 33, and the pixel electrode 51 is provided corresponding to the common electrode 42.

Referring to FIG. 9E, a third insulating film is deposited on the gate 41, and a yellow light process is performed on the third insulating film using a sixth photomask to form the third insulating layer 13. A second via hole 131 is disposed at a position of the third insulating layer 13 corresponding to the drain contact portion 33. The second via hole 131 penetrates the third insulating layer 13 and exposes at least a part of the drain contact portion 33.

Referring to FIG. 9F, a second conductive film is deposited on the third insulating layer 13, and a yellow light process is performed on the second conductive film using a sixth photomask to form the third conductive layer 50. The third conductive layer 50 includes the pixel electrode 51 connected to the drain contact portion 33, and the pixel electrode 51 is provided corresponding to the common electrode 42.

As described above, in the preparing method of the array substrate of the present embodiment, a total of 6 photomasks are required to form the array substrate 100 of the present application. Compared with the array substrate 100 of the example of FIG. 1, which requires 10 photomasks, the array substrate 100 of the example of FIG. 4 requires only 6 photomasks, which reduces the number of photomasks used and thus reduces the cost. Furthermore, in case where preparing the gate 41 and the common electrode 42, deposition by a process such as magnetron sputtering or vacuum vapor deposition can be adopted, so that deposition by a physical vapor deposition method can be skipped, and the number of machines required for the physical vapor deposition process can be reduced, and thus, the cost can be further reduced by reducing the number of machines required for the physical vapor deposition process while reducing the number of photomasks used and reducing the cost.

Based on the same inventive concept, an embodiment of the present application further provides a display panel including the array substrate 100 according to one of the above embodiments. The display panel includes a liquid crystal display panel or the like.

According to the above embodiments, it can be seen that:

In the array substrate, the preparing method thereof, and the display panel, the array substrate includes a substrate, a first conductive layer, an active layer, a second conductive layer, and a third conductive layer all provided on the substrate, a source contact portion of the active layer is connected to a source of the first conductive layer, the second conductive layer includes a gate provided corresponding to a channel portion, a pixel electrode of the third conductive layer is connected to a drain contact portion of the active layer, and at least one of the first conductive layer and the second conductive layer further includes a common electrode provided corresponding to the pixel electrode. As described above, by disposing the source and the light-shielding electrode in the same layer, and disposing the common electrode in the same layer as at least one of the gate and the light-shielding electrode, the number of photomasks to be used can be reduced and the cost can be reduced.

In the above-described embodiments, the description of each embodiment has its own emphasis, and for parts not described in detail in a certain embodiment, please refer to the related description of other embodiments.

The embodiments of the present application have been described in detail above, and the principles and embodiments of the present application have been described herein by applying specific examples, and the description of the above embodiments is only for helping to understand the technical solutions and core ideas of the present application. Those skilled in the art should understand that the technical solutions described in the above embodiments can still be modified, or some technical features can be equivalently replaced. However, these modifications or substitutions do not cause the essence of the corresponding technical solutions to deviate from the scope of the technical solutions of each embodiment of the present application.

What is claimed is:

1. An array substrate, comprising:
a substrate;
a first conductive layer provided on a side of the substrate; wherein the first conductive layer comprises a source and a light-shielding electrode disposed apart from each other;
an active layer provided on a side of the first conductive layer away from the substrate; wherein the active layer is provided corresponding to the light-shielding electrode;
a second conductive layer provided on a side of the active layer away from the substrate, wherein the second conductive layer comprises a gate provided corresponding to the active layer; and
a third conductive layer provided on a side of the second conductive layer away from the substrate, wherein the third conductive layer comprises a pixel electrode connected to the active layer; and
wherein at least one of the first conductive layer and the second conductive layer further comprises a common electrode disposed corresponding to the pixel electrode.

2. The array substrate of claim 1, wherein at least one of the first conductive layer and the second conductive layer further comprises a transparent conductive sub-layer, and the transparent conductive sub-layer forms the common electrode.

3. The array substrate of claim 2, wherein a material of the transparent conductive sub-layer comprises indium tin oxide.

4. The array substrate of claim 2, wherein the second conductive layer comprises the transparent conductive sub-layer, and the transparent conductive sub-layer further forms the gate.

5. The array substrate according to claim 4, wherein the second conductive layer further comprises one or more metal sub-layers disposed on a side of the transparent conductive sub-layer away from the substrate, and the metal sub-layer and the transparent conductive sub-layer form the gate.

6. The array substrate according to claim 2, wherein the first conductive layer comprises the transparent conductive sub-layer and one or more metal sub-layers disposed on a side of the transparent conductive sub-layer away from the substrate, and the metal sub-layer and the transparent conductive sub-layer form the source and the light-shielding electrode.

7. The array substrate according to claim 1, wherein a distance between the gate and the substrate is larger than a distance between the common electrode and the substrate in a thickness direction of the array substrate.

8. The array substrate according to claim 1, wherein the active layer comprises a channel portion, the gate is provided corresponding to the channel portion, and the channel portion is provided corresponding to the light-shielding electrode in a thickness direction of the array substrate.

9. The array substrate according to claim 1, wherein the active layer further comprises a source contact portion and a drain contact portion, the channel portion is connected between the source contact portion and the drain contact portion, the source contact portion is connected to the source, and the pixel electrode is connected to the drain contact portion.

10. The array substrate of claim 8, further comprising:
a first insulating layer located between the substrate and the first conductive layer; wherein a first via hole is disposed in a position of the first insulating layer corresponding to the source, and the source contact portion is connected to the source through the first via hole;
a second insulating layer located between the active layer and the second conductive layer, wherein the second insulating layer comprises a first insulating portion disposed corresponding to the gate; and
a third insulating layer located between the second conductive layer and the third conductive layer, wherein a second via hole is disposed in a position of the third insulating layer corresponding to the drain contact, and the pixel electrode is connected to the drain contact portion through the second via hole.

11. A preparing method for an array substrate, comprising:
providing a substrate on a side of which a first conductive layer is prepared, wherein the first conductive layer comprises a source and a light-shielding electrode disposed apart from each other;
preparing an active layer on a side of the first conductive layer away from the substrate, wherein a part of the active layer is connected to the source;
preparing a second conductive layer comprising a gate on a side of the active layer away from the substrate, and conductorizing the active layer with the gate as a shield to form a channel portion, a source contact portion, and a drain contact portion; wherein the gate is provided corresponding to a part of the active layer, the second conductive layer further comprises a common electrode provided spaced apart from the gate, and the channel portion is connected between the source contact portion and the drain contact portion; and in a thickness direction of the array substrate, the channel portion is provided corresponding to the light-shielding electrode, and the source contact portion is connected to the source; and
preparing a third conductive layer on a side of the second conductive layer away from the substrate, wherein the third conductive layer comprises a pixel electrode connected to the drain contact portion, and the pixel electrode is disposed corresponding to the common electrode.

12. A display panel, comprising an array substrate, and the array substrate comprises:
a substrate;
a first conductive layer provided on a side of the substrate; wherein the first conductive layer comprises a source and a light-shielding electrode disposed apart from each other;
an active layer provided on a side of the first conductive layer away from the substrate; wherein the active layer is provided corresponding to the light-shielding electrode;
a second conductive layer provided on a side of the active layer away from the substrate, wherein the second conductive layer comprises a gate provided corresponding to the active layer; and
a third conductive layer provided on a side of the second conductive layer away from the substrate, wherein the third conductive layer comprises a pixel electrode connected to the active layer; and
wherein at least one of the first conductive layer and the second conductive layer further comprises a common electrode disposed corresponding to the pixel electrode.

13. The display panel of claim 12, wherein at least one of the first conductive layer and the second conductive layer further comprises a transparent conductive sub-layer, and the transparent conductive sub-layer forms the common electrode.

14. The display panel of claim 13, wherein a material of the transparent conductive sub-layer comprises indium tin oxide.

15. The display panel of claim 13, wherein the second conductive layer comprises the transparent conductive sub-layer, and the transparent conductive sub-layer further forms the gate.

16. The display panel according to claim 15, wherein the second conductive layer further comprises one or more metal sub-layers disposed on a side of the transparent conductive sub-layer away from the substrate, and the metal sub-layer and the transparent conductive sub-layer form the gate.

17. The display panel according to claim 13, wherein the first conductive layer comprises the transparent conductive sub-layer and one or more metal sub-layers disposed on a side of the transparent conductive sub-layer away from the substrate, and the metal sub-layer and the transparent conductive sub-layer form the source and the light-shielding electrode.

18. The display panel according to claim 12, wherein a distance between the gate and the substrate is larger than a distance between the common electrode and the substrate in a thickness direction of the array substrate.

19. The display panel according to claim 12, wherein the active layer comprises a channel portion, a source contact portion, and a drain contact portion; the channel portion is connected between the source contact portion and the drain contact portion; the source contact portion is connected to the source electrode, the gate electrode is disposed corresponding to the channel portion, and the channel portion is disposed corresponding to the light shielding electrode in a thickness direction of the array substrate; and the pixel electrode is connected to the drain contact.

20. The display panel of claim 19, the array substrate further comprises:
a first insulating layer located between the substrate and the first conductive layer; wherein a first via hole is disposed in a position of the first insulating layer corresponding to the source, and the source contact portion is connected to the source through the first via hole;
a second insulating layer located between the active layer and the second conductive layer, wherein the second insulating layer comprises a first insulating portion disposed corresponding to the gate; and
a third insulating layer located between the second conductive layer and the third conductive layer, wherein a second via hole is disposed in a position of the third insulating layer corresponding to the drain contact, and the pixel electrode is connected to the drain contact portion through the second via hole.
